(19) United States
(12) Patent Application Publication
(10) Pub. No.: US 2016/0215392 A1
(43) Pub. Date: Jul. 28, 2016

(54) Injector For Spatially Separated Atomic Layer Deposition Chamber

(71) Applicant: Applied Materials, Inc., Santa Clara, CA (US)

(72) Inventors: Joseph Yudovsky, Campbell, CA (US); Kevin Griffin, Livermore, CA (US); Aaron Miller, Sunnyvale, CA (US); Jeff Tobin, Mountain View, CA (US); Eran Newman, Palo Alto, CA (US); Tatsuya E. Sato, San Jose, CA (US); Patricia M. Liu, Saratoga, CA (US)

(21) Appl. No.: 15/001,710

(22) Filed: Jan. 20, 2016

Related U.S. Application Data
(60) Provisional application No. 62/106,407, filed on Jan. 22, 2015.

(51) Int. Cl. C23C 16/455

(52) U.S. Cl. CPC C23C 16/455

(57) ABSTRACT

Apparatus and methods for spatial atomic layer deposition are disclosed. The apparatus include a gas delivery system comprising a first gas flowing through a plurality of legs in fluid communication with a valve and a second gas flowing through a plurality of legs into the valves.

### CROSS-REFERENCE TO RELATED APPLICATIONS

This application claims priority to United States Provisional Application No. 62/106,407, filed Jan. 22, 2015, the entire contents of which are hereby incorporated by reference herein.

### FIELD

Embodiments of the disclosure generally relate to an apparatus for processing substrates. More particularly, embodiments of the disclosure relate to apparatus and methods for controlling the gas flow within the processing chamber.

### BACKGROUND

Semiconductor device formation is commonly conducted in substrate processing systems or platforms containing multiple chambers, which may also be referred to as cluster tools. In some instances, the purpose of a multi-chamber processing platform or cluster tool is to perform two or more processes on a substrate sequentially in a controlled environment. In other instances, however, a multiple chamber processing platform may only perform a single processing step on substrates. The additional chambers can be employed to maximize the rate at which substrates are processed. In the latter case, the process performed on substrates is typically a batch process, wherein a relatively large number of substrates, e.g. 25 or 50, are processed in a given chamber simultaneously. Batch processing is especially beneficial for processes that are too time-consuming to be performed on individual substrates in an economically viable manner, such as for atomic layer deposition (ALD) processes and some chemical vapor deposition (CVD) processes.

The concept of spatial ALD is based on a clear separation of different gas phase reactive chemicals. Mixing of the chemicals is prevented to avoid gas phase reactions. The general design of a spatial ALD chamber may include a small gap between susceptor (or wafer surface) and gas injector. This gap can be in the range of about 0.5 mm to about 2.5 mm. Vacuum pumping channels are positioned around each chemical showerhead. Inert gas purge channels are between the chemical showerheads to minimize gas phase mixing. While current injector designs are able to prevent gas phase mixing the reactive species, the injectors do not provide enough control over where and when precursor exposure happens. There is an ongoing need in the art for apparatus and methods for controlling the flow of gases into a processing chamber.

SUMMARY

One or more embodiments of the disclosure are directed to gas delivery systems comprising a first inlet line in fluid communication with a first junction. At least two first legs are connected to and in fluid communication with the first junction. Each of the at least two first legs are in fluid communication with at least one valve. A second inlet line is in fluid communication with each valve. An outlet leg is in fluid communication with each valve and ending in an outlet end. Each valve controls a flow of fluid from the first legs to the outlet leg. The distance from the first junction to each of the outlet ends are substantially the same.

Some embodiments are directed to gas delivery system comprising a first inlet line in fluid communication with a first junction. Two first legs are connected to and in fluid communication with the first junction. Each of the at least two first legs is in fluid communication with a second junction. Two second legs are in fluid communication with each of the second junctions and a valve. A second inlet line is in fluid communication with each of the valves. An outlet leg is in fluid communication with each of the valves and having an outlet end. Each valve controls a flow of fluid from the first legs to the outlet leg. The distance from the first junction through the second junction to each of the outlet ends are substantially the same.

One or more embodiments of the disclosure are directed to processing chambers comprising a gas distribution assembly. The gas distribution assembly comprises a plurality of elongate gas ports including at least one first reactive gas port and at least one second reactive gas port. Each of the first reactive gas ports is separated from each of the second reactive gas ports. A first gas delivery system is in fluid communication with one of the first reactive gas ports and the second reactive gas ports. The first gas delivery system comprises a first inlet line in fluid communication with a first junction. At least two first legs are connected to and in fluid communication with the first junction. Each of the at least two first legs is in fluid communication with at least one valve. A second inlet line is in fluid communication with each valve. An outlet leg is in fluid communication with each valve and one of the plurality of first reactive gas port or the second reactive gas ports. Each valve controls a flow of fluid from the first legs to the outlet leg. The distance from the first junction to each of the outlet ends are substantially the same.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. However, that the appended drawings illustrate only typical embodiments of this disclosure and are therefore not to be considered limiting of scope, for the disclosure may admit to other equally effective embodiments.

FIG. 1 is a cross-sectional side view of a spatial atomic layer deposition chamber in accordance with one or more embodiment of the disclosure;

FIG. 2 is a schematic plan view of a substrate processing system configured with four gas distribution assembly units with a loading station in accordance with one or more embodiments of the disclosure;

FIG. 3 shows a cross-sectional view of a processing chamber in accordance with one or more embodiments of the disclosure;

FIG. 4 shows a perspective view of a susceptor assembly and gas distribution assembly units in accordance with one or more embodiments of the disclosure;

FIG. 5 shows a cross-sectional view of a processing chamber in accordance with one or more embodiments of the disclosure;

FIG. 6 shows a schematic of a pie-shaped gas distribution assembly in accordance with one or more embodiments of the disclosure;

FIG. 7 shows a schematic of a gas distribution assembly in accordance with one or more embodiment of the disclosure;

FIG. 8 shows a schematic of a gas delivery system in accordance with one or more embodiment of the disclosure;

FIG. 9 shows a schematic of a gas delivery system in accordance with one or more embodiment of the disclosure;

FIG. 10 shows a schematic of a gas delivery system in accordance with one or more embodiment of the disclosure; and

FIG. 11 shows a schematic shows a schematic of two gas delivery systems in accordance with one or more embodiment of the disclosure.

### DETAILED DESCRIPTION

Embodiments of the disclosure provide a substrate processing system for continuous substrate deposition to maximize throughput and improve processing efficiency and uniformity. The substrate processing system can also be used for pre-deposition and post-deposition substrate treatments. Embodiments of the disclosure are related to apparatus and methods for increasing deposition uniformity in a batch processor.

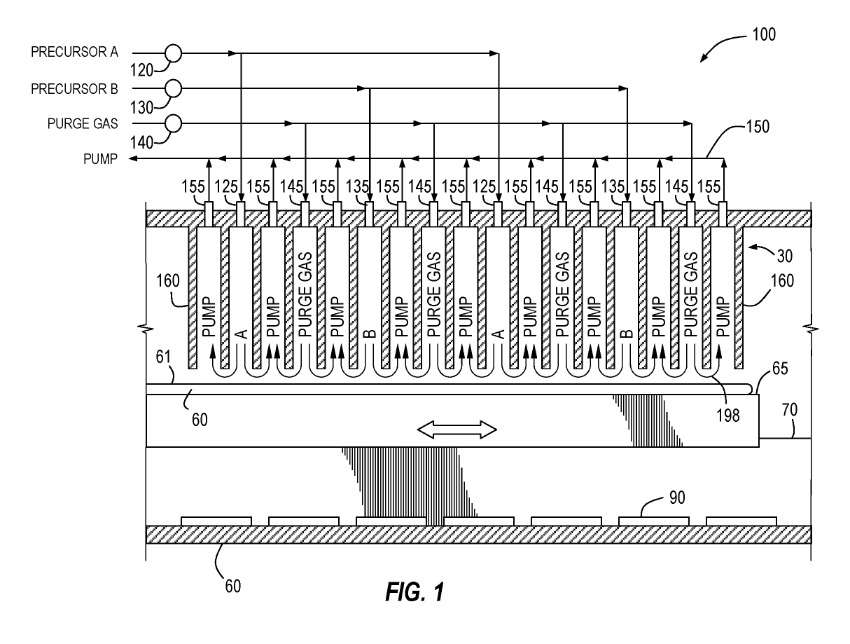

As used in this specification and the appended claims, the term “substrate” and “wafer” are used interchangeably, both referring to a surface, or portion of a surface, upon which a process acts. Those skilled in the art will understand that reference to a substrate can also refer to only a portion of the substrate, unless the context clearly indicates otherwise. For example, in spatially separated ALD, described with respect to FIG. 1, each precursor is delivered to the substrate, but any individual precursor stream, at any given time, is only delivered to a portion of the substrate. Additionally, reference to depositing on a substrate can mean both a bare substrate and a substrate with one or more films or features deposited or formed thereon.

As used in this specification and the appended claims, the terms “reactive gas”, “process gas”, “precursor”, “reactant”, and the like, are used interchangeably to mean a gas that includes a species which is reactive in an atomic layer deposition process. For example, a first “reactive gas” may simply adsorb onto the surface of a substrate and be available for further chemical reaction with a second reactive gas.

Embodiments of the disclosure are directed to methods and apparatus to improved injector designs for spatial atomic layer deposition (ALD) chambers which allow precise control of when and where precursor exposure happens. The added control of some embodiments may help improve several manufacturability requirements including, but not limited to, film profile matching and wafer to wafer matching. Current injector designs may not provide enough control and, as a result, might show some limitations with respect to film profile matching and wafer to wafer matching.

FIG. 1 is a schematic cross-sectional view of a portion of a processing chamber 100 in accordance with one or more embodiments of the disclosure. The processing chamber 100 is generally a sealable enclosure, which is operated under vacuum or at least low pressure conditions. The system includes a gas distribution assembly 30 capable of distributing one or more gases across the top surface 61 of a substrate 60. The gas distribution assembly 30 can be any suitable assembly known to those skilled in the art, and specific gas distribution assemblies described should not be taken as limiting the scope of the disclosure. The output face of the gas distribution assembly 30 faces the top surface 61 of the substrate 60.

Substrates for use with the embodiments of the disclosure can be any suitable substrate. In some embodiments, the substrate is a rigid, discrete, generally planar substrate. As used in this specification and the appended claims, the term “discrete” when referring to a substrate means that the substrate has a fixed dimension. The substrate of one or more embodiments is a semiconductor substrate, such as a 200 mm or 300 mm diameter silicon substrate. In some embodiments, the substrate is one or more of silicon, silicon germanium, gallium arsenide, gallium nitride, germanium, gallium phosphide, indium phosphide, sapphire and silicon carbide.

The gas distribution assembly 30 comprises a plurality of gas ports to transmit one or more gas streams to the substrate 60 and a plurality of vacuum ports disposed between each gas port to transmit the gas streams out of the processing chamber 100. In the embodiment of FIG. 1, the gas distribution assembly 30 comprises a first precursor injector 120, a second precursor injector 130 and a purge gas injector 140. The injectors 120, 130, 140 may be controlled by a system computer (not shown), such as a mainframe, or by a chamber-specific controller, such as a programmable logic controller. The precursor injector 120 injects a continuous (or pulse) stream of a reactive precursor of compound A into the processing chamber 100 through a plurality of gas ports 125. The precursor injector 130 injects a continuous (or pulse) stream of a reactive precursor of compound B into the processing chamber 100 through a plurality of gas ports 135. The purge gas injector 140 injects a continuous (or pulse) stream of a non-reactive or purge gas into the processing chamber 100 through a plurality of gas ports 145. The purge gas removes reactive material and reactive by-products from the processing chamber 100. The purge gas is typically an inert gas, such as, nitrogen, argon and helium. Gas ports 145 are disposed in between gas ports 125 and gas ports 135 so as to separate the precursor of compound A from the precursor of compound B, avoiding cross-contamination between the precursors.

In another aspect, a remote plasma source (not shown) may be connected to the precursor injector 120 and the precursor injector 130 prior to injecting the precursors into the processing chamber 100. The plasma of reactive species may be generated by applying an electric field to a compound within the remote plasma source. Any power source that is capable of activating the intended compounds may be used. For example, power sources using DC, radio frequency (RF), and microwave (MW) based discharge techniques may be used. If an RF power source is used, the power source can be either capacitively or inductively coupled. The activation may also be generated by a thermally based technique, a gas breakdown technique, a high energy light source (e.g., UV energy), or exposure to an x-ray source. Exemplary remote plasma sources are available from vendors such as MKS Instruments, Inc. and Advanced Energy Industries, Inc.

The system may a pumping system connected to the processing chamber. The pumping system is generally configured to evacuate the gas streams out of the processing chamber through one or more vacuum ports. The vacuum ports are disposed between each gas port so as to evacuate the gas streams out of the processing chamber after the gas streams react with the substrate surface and to further limit cross-contamination between the precursors.

The system includes a plurality of partitions 160 disposed on the processing chamber 100 between each port. A lower portion of each partition extends close to the first surface 61 of substrate 60, for example, about 0.5 mm or greater from the first surface 61. In this manner, the lower portions of the partitions 160 are separated from the substrate surface by a distance sufficient to allow the gas streams to flow around the lower portions toward the vacuum ports 155 after the gas streams react with the substrate surface. Arrows 198 indicate the direction of the gas streams. Since the partitions 160 operate as a physical barrier to the gas streams, they also limit cross-contamination between the precursors. The arrangement shown is merely illustrative and should not be taken as limiting the scope of the disclosure. Those skilled in the art will understand that the gas distribution system shown is merely one possible distribution system and the other types of showerheads and gas distribution assemblies may be employed.

Atomic layer deposition systems of this sort (i.e., where multiple gases are separately flowed toward the substrate at the same time) are referred to as spatial ALD. In operation, a substrate 60 is delivered (e.g., by a robot) to the processing chamber 100 and can be placed on a shuttle 65 before or after entry into the processing chamber. The shuttle 65 is moved along the track 70, or some other suitable movement mechanism, through the processing chamber 100, passing beneath (or above) the gas distribution assembly 30. In the embodiment shown in FIG. 1, the shuttle 65 is moved in a linear path through the chamber. In some embodiments, wafers are moved in a circular path through a carousel processing system.

Referring back to FIG. 1, as the substrate 60 moves through the processing chamber 100, the first surface 61 of substrate 60 is repeatedly exposed to the reactive gas A coming from gas ports 125 and reactive gas B coming from gas ports 135, with the purge gas coming from gas ports 145 in between. Injection of the purge gas is designed to remove unreacted material from the previous precursor prior to exposing the substrate surface 110 to the next precursor. After each exposure to the various gas streams (e.g., the reactive gases or the purge gas), the gas streams are evacuated through the vacuum ports 155 by the pumping system. Since a vacuum port may be disposed on both sides of each gas port, the gas streams are evacuated through the vacuum ports 155 on both sides. Thus, the gas streams flow from the respective gas ports vertically downward toward the first surface 61 of the substrate 60, across the substrate surface 110 and around the lower portions of the partitions 160, and finally upward toward the vacuum ports 155. In this manner, each gas may be uniformly distributed across the substrate surface 110. Arrows 198 indicate the direction of the gas flow. Substrate 60 may also be rotated while being exposed to the various gas streams. Rotation of the substrate may be useful in preventing the formation of strips in the formed layers. Rotation of the substrate can be continuous or in discrete steps and can occur while the substrate is passing beneath the gas distribution assembly 30 or when the substrate is in a region before and/or after the gas distribution assembly 30.

Sufficient space is generally provided after the gas distribution assembly 30 to ensure complete exposure to the last gas port. Once the substrate 60 has completely passed beneath the gas distribution assembly 30, the first surface 61 has completely been exposed to every gas port in the processing chamber 100. The substrate is then transported back in the opposite direction or forward. If the substrate 60 moves in the opposite direction, the substrate surface may be exposed again to the reactive gas A, the purge gas, and reactive gas B, in reverse order from the first exposure.

The extent to which the substrate surface 110 is exposed to each gas may be determined by, for example, the flow rates of each gas coming out of the gas port and the rate of movement of the substrate 60. In one embodiment, the flow rates of each gas are controlled so as not to remove adsorbed precursors from the substrate surface 61. The width between each partition, the number of gas ports disposed on the processing chamber 100, and the number of times the substrate is passed across the gas distribution assembly may also determine the extent to which the substrate surface 61 is exposed to the various gases. Consequently, the quantity and quality of a deposited film may be optimized by varying the above-referenced factors.

Although description of the process has been made with the gas distribution assembly 30 directing a flow of gas downward toward a substrate positioned below the gas distribution assembly, this orientation can be different. In some embodiments, the gas distribution assembly 30 directs a flow of gas upward toward a substrate surface. As used in this specification and the appended claims, the term “passed across” means that the substrate has been moved from one side of the gas distribution assembly to the other side so that the entire surface of the substrate is exposed to each gas stream from the gas distribution plate. Absent additional description, the term “passed across” does not imply any particular orientation of gas distribution assemblies, gas flows or substrate positions.

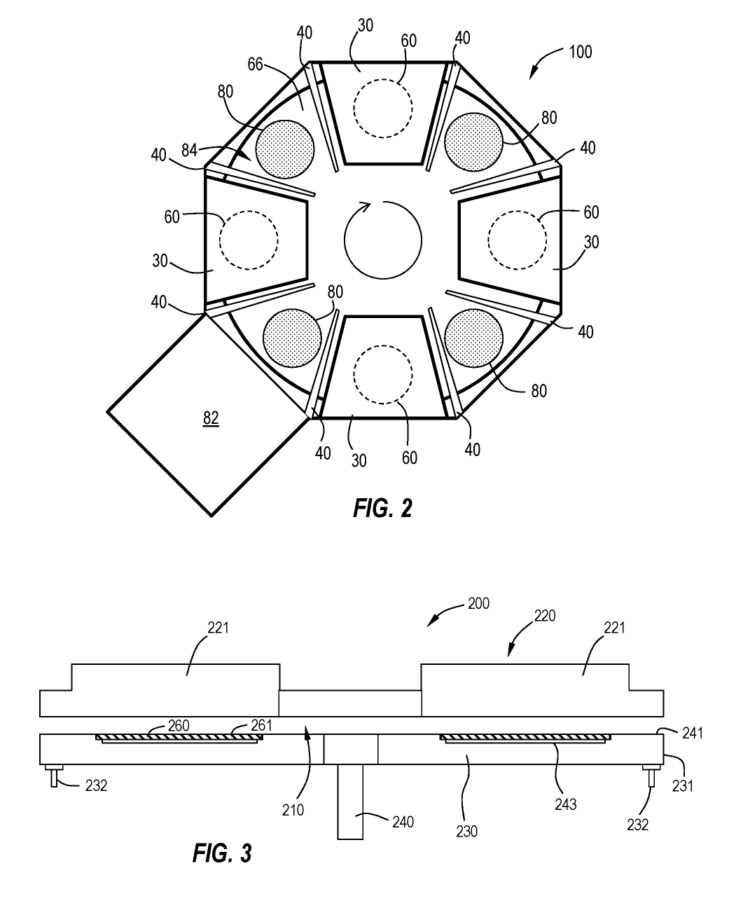

In some embodiments, the shuttle 65 is a carrier which helps to form a uniform temperature across the substrate. The susceptor is movable in both directions (left-to-right and right-to-left, relative to the arrangement of FIG. 1) or in a circular direction (relative to FIG. 2). The susceptor has a top surface for carrying the substrate 60. The susceptor may be a heated susceptor so that the substrate 60 may be heated for processing. As an example, the susceptor 66 may be heated by radiant heat lamps 90, a heating plate, resistive coils, or other heating devices, disposed underneath the susceptor.

FIG. 1 shows a cross-sectional view of a processing chamber in which the individual gas ports are shown. This embodiment can be either a linear processing system in which the width of the individual gas ports is substantially the same across the entire width of the gas distribution plate, or a pie-shaped segment in which the individual gas ports change width to conform to the pie shape. FIG. 3 shows a portion of a pie-shaped gas distribution assembly 220.

Processing chambers having multiple gas injectors can be used to process multiple wafers simultaneously so that the wafers experience the same process flow. This is often referred to as batch processing or a batch processing chamber. For example, as shown in FIG. 2, the processing chamber 100 has four gas distribution assemblies 30 and four substrates 60. At the outset of processing, the substrates 60 can be positioned between the gas distribution assemblies 30. Rotating the susceptor 66 of the carousel by 45° will result in each substrate 60 being moved to an injector assembly 30 for film deposition. This is the position shown in FIG. 2. An additional 45° rotation would move the substrates 60 away from the gas distribution assemblies 30. With spatial ALD injectors, a film is deposited on the wafer during movement of the wafer relative to the injector assembly. In some embodiments, the susceptor 66 is rotated so that the substrates 60 do not stop beneath the gas distribution assemblies 30. The number of substrates 60 and gas distribution assemblies 30 can be the same or different. In some embodiments, there is the same number of wafers being processed as there are gas distribution assemblies. In one or more embodiments, the number of wafers being processed are an integer multiple of the number of gas distribution assemblies. For example, if there are four gas distribution assemblies, there are 4x wafers being processed, where x is an integer value greater than or equal to one.

The processing chamber 100 shown in FIG. 2 is merely representative of one possible configuration and should not be taken as limiting the scope of the disclosure. Here, the processing chamber 100 includes a plurality of gas distribution assemblies 30. In the embodiment shown, there are four gas distribution assemblies 30 evenly spaced about the processing chamber 100. The processing chamber 100 shown is octagonal, however, those skilled in the art will understand that this is one possible shape and should not be taken as limiting the scope of the disclosure. The gas distribution assemblies 30 shown are rectangular, but those skilled in the art will understand that the gas distribution assemblies can be pie-shaped segments. Additionally, each segment can be configured to deliver gases in a spatial type arrangement with multiple different reactive gases flowing from the same segment or configured to deliver a single reactive gas or a mixture of reactive gases.

The processing chamber 100 includes a substrate support apparatus, shown as a round susceptor 66 or susceptor assembly. The substrate support apparatus, or susceptor 66, is capable of moving a plurality of substrates 60 beneath each of the gas distribution assemblies 30. A load lock 82 might be connected to a side of the processing chamber 100 to allow the substrates 60 to be loaded into or unloaded from the chamber 100.

The processing chamber 100 may include a plurality, or set, of first treatment stations 80 positioned between any or each of the plurality of gas distribution assemblies 30. In some embodiments, each of the first treatment stations 80 provides the same treatment to a substrate 60.

The number of treatment stations and the number of different types of treatment stations can vary depending on the process. For example, there can be one, two, three, four, five, six, seven or more treatment stations positioned between the gas distribution assemblies 30. Each treatment station can independently provide a different treatment from every other set of treatments station, or there can be a mixture of the same type and different types of treatments. In some embodiments, one or more of the individual treatments stations provides a different treatment than one or more of the other individual treatment stations. The embodiment shown in FIG. 2 shows four gas distribution assemblies with spaces between which can include some type of treatment station. However, one skilled in the art can easily envision from this drawing that the processing chamber can readily have, for example, eight gas distribution assemblies with the gas curtains between.

Treatment stations can provide any suitable type of treatment to the substrate, film on the substrate or susceptor assembly. For example, UV lamps, flash lamps, plasma sources and heaters. The wafers are then moved between positions with the gas distribution assemblies 30 to a position with, for example, a showerhead delivering plasma to the wafer. The plasma station being referred to as a treatment station 80. In one or more example, silicon nitride films can be formed with plasma treatment after each deposition layer. As the ALD reaction is, theoretically, self-limiting as long as the surface is saturated, additional exposure to the deposition gas will not cause damage to the film.

Rotation of the carousel can be continuous or discontinuous. In continuous processing, the wafers are constantly rotating so that they are exposed to each of the injectors in turn. In discontinuous processing, the wafers can be moved to the injector region and stopped, and then to the region 84 between the injectors and stopped. For example, the carousel can rotate so that the wafers move from an inter-injector region across the injector (or stop adjacent the injector) and on to the next inter-injector region where the substrate can pause again. Pausing between the injectors may provide time for additional processing steps between each layer deposition (e.g., exposure to plasma).

In some embodiments, the processing chamber comprises a plurality of gas curtains 40. Each gas curtain 40 creates a barrier to prevent, or minimize, the movement of processing gases from the gas distribution assemblies 30 from migrating from the gas distribution assembly regions and gases from the treatment stations 80 from migrating from the treatment station regions. The gas curtain 40 can include any suitable combination of gas and vacuum streams which can isolate the individual processing sections from the adjacent sections. In some embodiments, the gas curtain 40 is a purge (or inert) gas stream. In one or more embodiments, the gas curtain 40 is a vacuum stream that removes gases from the processing chamber. In some embodiments, the gas curtain 40 is a combination of purge gas and vacuum streams so that there are, in order, a purge gas stream, a vacuum stream and a purge gas stream. In one or more embodiments, the gas curtain 40 is a combination of vacuum streams and purge gas streams so that there are, in order, a vacuum stream, a purge gas stream and a vacuum stream. The gas curtains 40 shown in FIG. 2 are positioned between each of the gas distribution assemblies 30 and treatment stations 80, but the curtains can be positioned at any point or points along the processing path.

FIG. 3 shows an embodiment of a processing chamber 200 including a gas distribution assembly 220, also referred to as the injectors, and a susceptor assembly 230. In this embodiment, the susceptor assembly 230 is a rigid body. The rigid body of some embodiments has a droop tolerance no larger than 0.05 mm. Actuators 232 may be placed, for example, at three locations at the outer diameter region of the susceptor assembly 230. As used in this specification and the appended claims, the terms “outer diameter” and “inner diameter” refer to regions near the outer peripheral edge and the inner edge, respectively. The outer diameter does not refer to a specific position at the extreme outer edge of the susceptor assembly 230, but refers to a region near the outer edge 231 of the susceptor assembly 230. This can be seen in FIG. 3 from the placement of the actuators 232. The number of actuators 232 can vary from one to any number that will fit within the physical space available. Some embodiments have two, three, four or five sets of actuators 232 positioned in the outer diameter region 231. As used in this specification and the appended claims, the term “actuator” refers to any single or multi-component mechanism which is capable of moving the susceptor assembly 230, or a portion of the susceptor assembly 230, toward or away from the gas distribution assembly 220. For example, actuators 232 can be used to ensure that the susceptor assembly 230 is substantially parallel to the gas distribution assembly 220. As used in this specification and the appended claims, the term “substantially parallel” used in this regard means that the parallelism of the components does not vary by more than 5% relative to the distance between the components.

Once pressure is applied to the susceptor assembly 230 from the actuators 232, the susceptor assembly 230 can be levelled. As the pressure is applied by the actuators 232, the gap 210 distance can be set to be within the range of about 0.1 mm to about 2.0 mm, or in the range of about 0.2 mm to about 1.8 mm, or in the range of about 0.3 mm to about 1.7 mm, or in the range of about 0.4 mm to about 1.6 mm, or in the range of about 0.5 mm to about 1.5 mm, or in the range of about 0.6 mm to about 1.4 mm, or in the range of about 0.7 mm to about 1.3 mm, or in the range of about 0.8 mm to about 1.2 mm, or in the range of about 0.9 mm to about 1.1 mm, or about 1 mm.

The susceptor assembly 230 is positioned beneath the gas distribution assembly 220. The susceptor assembly 230 includes a top surface 241 and, optionally, at least one recess 243 in the top surface 241. The recess 243 can be any suitable shape and size depending on the shape and size of the substrates 260 being processed. In the embodiment shown, the recess 243 has a step region around the outer peripheral edge of the recess 243. The steps can be sized to support the outer peripheral edge of the substrate 260. The amount of the outer peripheral edge of the substrate 260 that is supported by the steps can vary depending on, for example, the thickness of the wafer and the presence of features already present on the back side of the wafer.

In some embodiments, as shown in FIG. 3, the recess 243 in the top surface 241 of the susceptor assembly 230 is sized so that a substrate 260 supported in the recess 243 has a top surface 261 substantially coplanar with the top surface 241 of the susceptor assembly 230. As used in this specification and the appended claims, the term “substantially coplanar” means that the top surface of the wafer and the top surface of the susceptor assembly are coplanar within ±0.2 mm. In some embodiments, the top surfaces are coplanar within ±0.15 mm, ±0.10 mm or ±0.05 mm.

The susceptor assembly 230 of FIG. 3 includes a support post 240 which is capable of lifting, lowering and rotating the susceptor assembly 230. The susceptor assembly 230 may include a heater, or gas lines, or electrical components within the center of the support post 240. The support post 240 may be the primary means of increasing or decreasing the gap between the susceptor assembly 230 and the gas distribution assembly 220, moving the susceptor assembly 230 into rough position. The actuators 232 can then make micro-adjustments to the position of the susceptor assembly to create the predetermined gap.

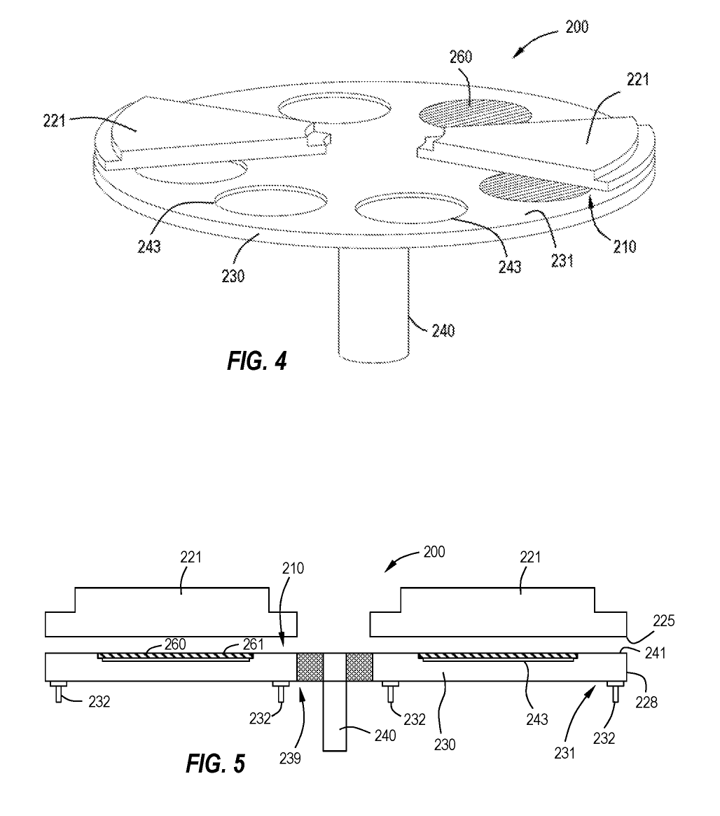

The processing chamber 100 shown in FIG. 3 is a carousel-type chamber in which the susceptor assembly 230 can hold a plurality of substrates 260. The gas distribution assembly 220 may include a plurality of separate injector units 221, each injector unit 221 being capable of depositing a film or part of a film on the substrate 260, as the wafer is moved beneath the injector unit 221. FIG. 4 shows a perspective view of a carousel-type processing chamber 200. Two pie-shaped injector units 221 are shown positioned on approximately opposite sides of and above the susceptor assembly 230. This number of injector units 221 is shown for illustrative purposes only. Those skilled in the art will understand that more or less injector units 221 can be included. In some embodiments, there are a sufficient number of pie-shaped injector units 221 to form a shape conforming to the shape of the susceptor assembly 230. In some embodiments, each of the individual pie-shaped injector units 221 may be independently moved, removed and/or replaced without affecting any of the other injector units 221. For example, one segment may be raised to permit a robot to access the region between the susceptor assembly 230 and gas distribution assembly 220 to load/unload substrates 260.

FIG. 5 shows another embodiment of the disclosure in which the susceptor assembly 230 is not a rigid body. In some embodiments, the susceptor assembly 230 has a droop tolerance of not more than about 0.1 mm, or not more than about 0.05 mm, or not more than about 0.025 mm, or not more than about 0.01 mm. In the embodiment of FIG. 5, actuators 232 placed at the outer diameter region 231 and at the inner diameter region 239 of the susceptor assembly 230. The actuators 232 can be positioned at any suitable number of places around the inner and outer periphery of the susceptor assembly 230. In some embodiments, the actuators 232 are placed at three locations at both the outer diameter region 231 and the inner diameter region 239. The actuators 232 at both the outer diameter region 231 and the inner diameter region 239 apply pressure to the susceptor assembly 230.

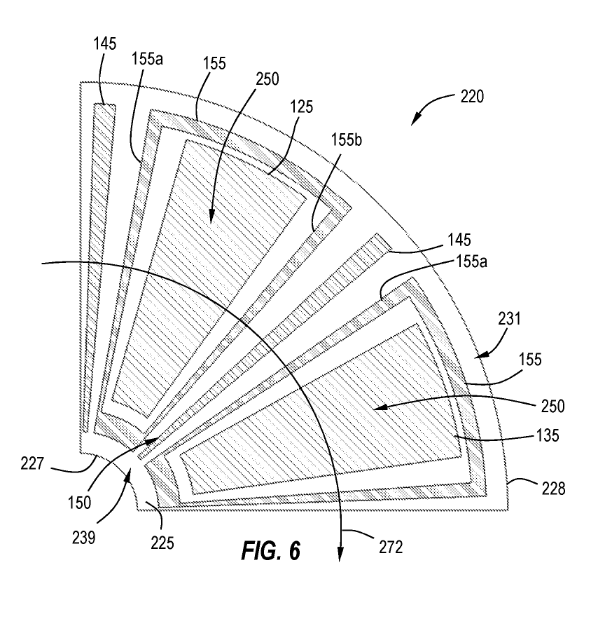

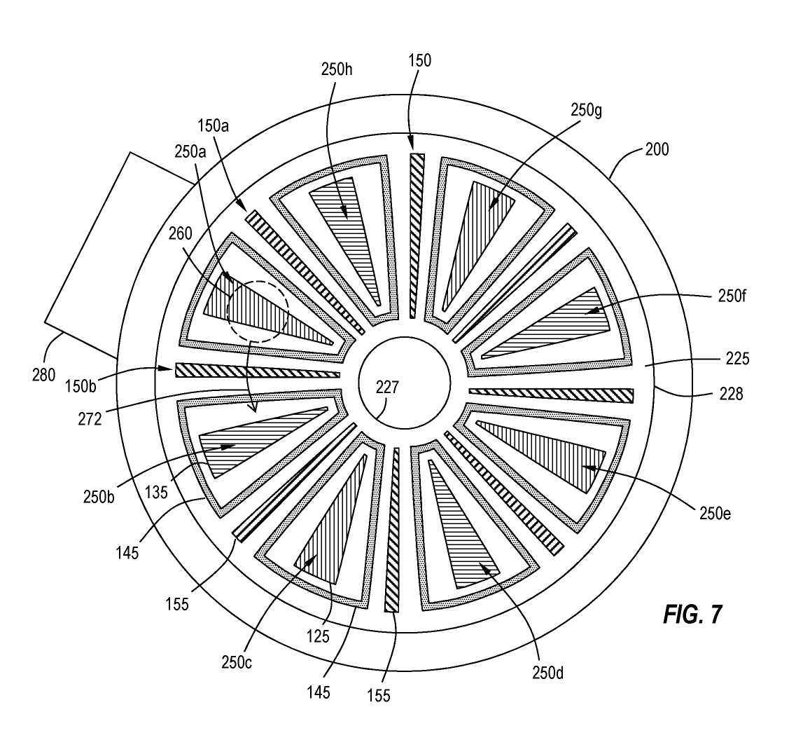

FIG. 6 shows a gas distribution assembly 220 in accordance with one or more embodiment of the disclosure. The front face 225 of a portion or segment of a generally circular gas distribution assembly 220 is shown. As used in this specification and the appended claims, the term “generally circular” means that the overall shape of the component does not have any internal angles less than 80°. Thus, generally circular can have any shape including square, pentagonal, hexagonal, heptagonal, octagonal, etc. Generally circular should not be taken as limiting the shape to a circle or perfect polygon, but can also include oval and imperfect polygons.

The gas distribution assembly 220 includes a plurality of elongate gas ports 125, 135, 145 in the front face 225. The gas ports extend from the inner diameter region 239 to an outer diameter region 231 of the gas distribution assembly 220. The plurality of gas ports include a first reactive gas port 125 to deliver a first reactive gas to the processing chamber and a purge gas port 145 to deliver a purge gas to the processing chamber. The embodiment shown in FIG. 7 also includes a second reactive gas port 135 to deliver a second reactive gas to the processing chamber.

The pie-shaped gas ports can have a narrower width near the inner peripheral edge 239 of the gas distribution assembly 220 and a larger width near the outer peripheral edge 231 of the gas distribution assembly 220. The shape or aspect ratio of the individual ports can be proportional to, or different from, the shape or aspect ratio of the gas distribution assembly segment. In some embodiments, the individual ports are shaped so that each point of a wafer passing across the gas distribution assembly 220 following path 272 would have about the same residence time under each gas port. The path of the substrates can be perpendicular to the gas ports. In some embodiments, each of the gas distribution assemblies comprises a plurality of elongate gas ports which extend in a direction substantially perpendicular to the path traversed by a substrate. As used in this specification and the appended claims, the term “substantially perpendicular” means that the general direction of movement is approximately perpendicular to the axis of the gas ports. For a pie-shaped gas port, the axis of the gas port can be considered to be a line defined as the mid-point of the width of the port extending along the length of the port. As described further below, each of the individual pie-shaped segments can be configured to deliver a single reactive gas or multiple reactive gases separated spatially or in combination (e.g., as in a typical CVD process).

A vacuum port 155 separates the first reactive gas port 125 and second reactive gas port 135 from the adjacent purge gas ports 145. Stated differently, the vacuum port is positioned between the first reactive gas port 125 and the purge gas port 145 and between the second reactive gas port 135 and the purge gas port 145. The vacuum ports evacuate gases from the processing chamber. In the embodiment shown in FIG. 6, the vacuum ports 155 extend around all sides of the reactive gas ports so that there is a portion of the vacuum port 155 on the inner peripheral edge 227 and outer peripheral edge 228 of each of the first reactive gas port 125 and second reactive gas port 135.

FIG. 6 shows a sector or portion of a gas distribution assembly 220, which may be referred to as an injector unit 122. The injector units 122 can be used individually or in combination with other injector units. For example, as shown in FIG. 7, four of the injector units 122 of FIG. 6 are combined to form a single gas distribution assembly 220. (The lines separating the four injector units are not shown for clarity.) While the injector unit 122 of FIG. 6 has both a first reactive gas port 125 and a second reactive gas port 135 in addition to purge gas ports 155 and vacuum ports 145, an injector unit 122 does not need all of these components.

Referring to both FIGS. 6 and 7, a gas distribution assembly 220 in accordance with one or more embodiment may comprise a plurality of sectors (or injector units 122) with each sector being identical or different. The gas distribution assembly 220 is positioned within the processing chamber and comprises a plurality of elongate gas ports 125, 135, 145 in a front surface 225 of the gas distribution assembly 220. The plurality of elongate gas ports 125, 135, 145 extend from an area adjacent the inner peripheral edge 123 toward an area adjacent the outer peripheral edge 228 of the gas distribution assembly 220. The plurality of gas ports shown include a first reactive gas port 125, a second reactive gas port 135, a purge gas port 145 which surrounds each of the first reactive gas ports and the second reactive gas ports and vacuum ports 155.

With reference to the embodiments shown in FIG. 6 or 7, when stating that the ports extend from at least about an inner peripheral region to at least about an outer peripheral region, the ports can extend more than just radially from inner to outer regions. The ports can extend tangentially as vacuum port 145 surrounds reactive gas port 125 and reactive gas port 135. In the embodiment shown in FIGS. 6 and 7, the wedge shaped reactive gas ports 125, 135 are surrounded on all edges, including adjacent the inner peripheral region and outer peripheral region, by a vacuum port 145.

Referring to FIG. 6, as a substrate moves along arcuate path 272, each portion of the substrate surface is exposed to the various reactive gases. To follow the path 272, the substrate will be exposed to, or “see”, a purge gas port 155, a vacuum port 145, a first reactive gas port 125, a vacuum port 145, a purge gas port 155, a vacuum port 145, a second reactive gas port 135 and a vacuum port 145. Thus, at the end of the path 272 shown in FIG. 6, the substrate has been exposed to the first reactive gas 125 and the second reactive gas 135 to form a layer. The injector unit 122 shown makes a quarter circle but could be larger or smaller. The gas distribution assembly 220 shown in FIG. 7 can be considered a combination of four of the injector units 122 of FIG. 6 connected in series.

The injector unit 122 of FIG. 6 shows a gas curtain 150 that separates the reactive gases. The term “gas curtain” is used to describe any combination of gas flows or vacuum that separate reactive gases from mixing. The gas curtain 150 shown in FIG. 6 comprises the portion of the vacuum port 145 next to the first reactive gas port 125, the purge gas port 155 in the middle and a portion of the vacuum port 145 next to the second reactive gas port 135. This combination of gas flow and vacuum can be used to prevent or minimize gas phase reactions of the first reactive gas and the second reactive gas.

Referring to FIG. 7, the combination of gas flows and vacuum from the gas distribution assembly 220 form a plurality of processing regions 250. The processing regions are roughly defined around the individual reactive gas ports 125, 135 with the gas curtain 150 between 250. The embodiment shown in FIG. 7 makes up eight separate processing regions 250 with eight separate gas curtains 150 between.

During processing a substrate may be exposed to more than one processing region 250 at any given time. However, the portions that are exposed to the different processing regions will have a gas curtain separating the two. For example, if the leading edge of a substrate enters a processing region including the second reactive gas port 135, a middle portion of the substrate will be under a gas curtain 150 and the trailing edge of the substrate will be in a processing region including the first reactive gas port 125.

A factory interface 280, which can be, for example, a load lock chamber, is shown connected to the processing chamber 200. A substrate 260 is shown superimposed over the gas distribution assembly 220 to provide a frame of reference. While not required, the substrate 260 will often sit on a susceptor assembly to be held near the front surface 225 of the gas distribution assembly 220. The substrate 260 is loaded via the factory interface 280 into the processing chamber 200 onto a substrate support or susceptor assembly. The substrate 260 can be shown positioned within a processing region because the substrate is located adjacent the first reactive gas port 125 and between two gas curtains 150a, 150b. Rotating the substrate 60 along path 272 will move the substrate counter-clockwise around the processing chamber 200. The substrate 260 will be exposed to the first processing region 250a through the eighth processing region 250h, including all processing regions between. For each cycle around the processing chamber, using the gas distribution assembly shown, the substrate 260 will be exposed to four ALD cycles of first reactive gas and second reactive gas.

Some deposition processes may have within wafer (WiW) profile mismatching between the various pockets (recesses) in the susceptor assembly within a batch. The WiW profile mismatch may present a challenge to the implementation of various processes. The inventors have discovered that the wafer location modulation correlates between the injector location and the WiW profile. The injector and wafer location during certain process steps may affect the WiW profile.

Embodiments of the valve manifolds, which feed all injectors for a given precursor (reactive gas), enable the flow of nitrogen only or nitrogen and precursor. The flow of nitrogen is helpful to ensure proper spatial separation is achieved throughout the process, even when precursors are not present. Some embodiments of the disclosure include a valve on all of the injectors for a given precursor instead of on a given precursor for all injectors. Embodiments of the disclosure provide more accurate and precise control of precursor exposure on the substrates.

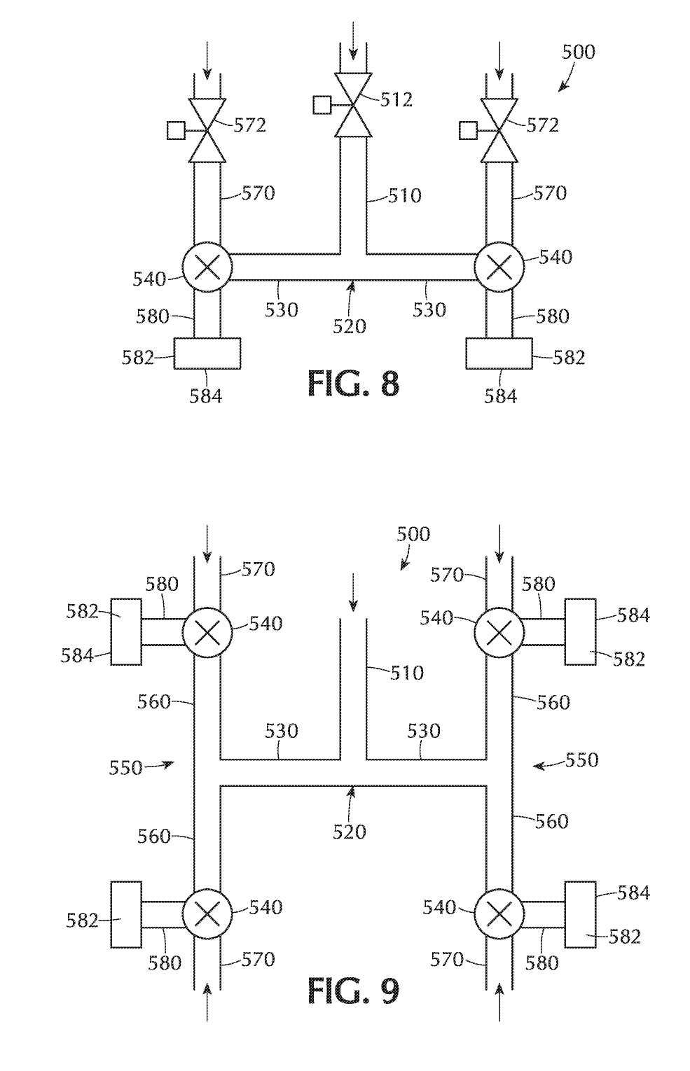

FIGS. 8 to 10 show gas delivery systems 500 in accordance with one or more embodiment of the disclosure. A first inlet line 510 is in fluid communication with a first junction 520. The first inlet line 510 can be connected to a gas source, for example, a precursor ampoule. As used in this specification and the appended claims, the term “fluid communication” means that a fluid (e.g., a precursor containing gas) can flow from one designated component to another designated component within the enclosed system without significant leakage. Some embodiments include a cut-off valve 512 in fluid communication with the first inlet line 510 upstream of the first valve 520. The cut-off valve 512 can be closed to prevent any gas from flowing toward the first junction 520 or from the first junction 520.

The first junction 520, and other junctions, can be any suitable component that can split the gas flow. For example, a wye or a proportioning valve. In some embodiments, the first junction 520 is a wye or t-shaped connector. In some embodiments, the junctions split the gas flow into substantially equal amounts. As used in this specification and the appended claims, the term “substantially equal amounts” means that the amount of gas flowing through each leg leaving the junction is within 10% or 5% or 2% or 1%. For example, the first junction of FIG. 8 splits the flow so that in the range of 40:60 to 60:40, or in the range of 45:55 to 55:45 or in the range of about 48:52 to 52:48, or in the range of 49:51 to 51:49.

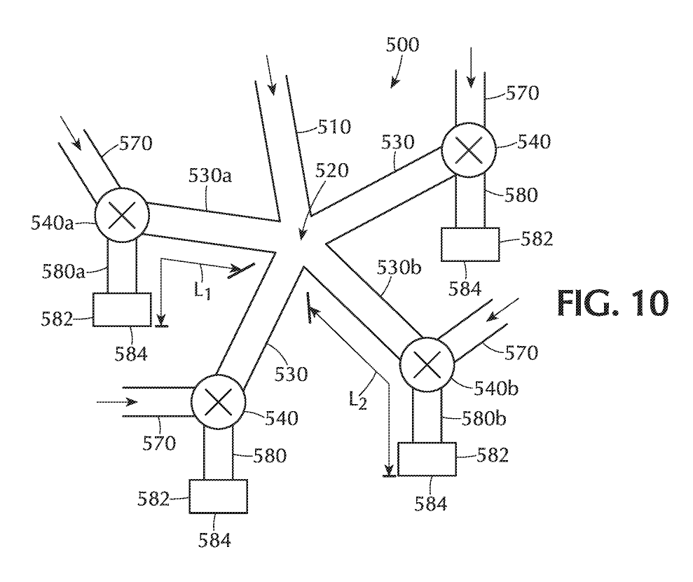

At least two first legs 530 are connected to and in fluid communication with the first junction 520. Each of the at least two first legs 530 is in fluid communication with at least one valve 540. The embodiments shown in FIGS. 8 and 9 each have two first legs 530 extending from the first junction 520. The embodiment shown in FIG. 10 has four first legs 530 extending from the first junction 520.

Referring to FIG. 9, each of the first legs 520 is independently in fluid communication with a second junction 550 located downstream of the first junction 520. At least two second legs 560 extend from each of the second junctions 550 leading to the valves 540. In the embodiment of FIG. 9 there are two second legs 560 in fluid communication with each of the second junctions 550 and a valve 540. Some embodiments have more than two second legs 560 extending from the second junction 550. For example, if four second legs 560 extend from each of the second junctions 550 and connect to a valve 540, there will be a total of eight valves 540 that can be connected to other components.

A second inlet line 570 is in fluid communication with each valve 540. The second inlet line 570 can be connected to any suitable gas source, for example, a nitrogen gas line. In the embodiment of FIG. 8, the gas flowing through the second inlet line 570 flows into the same valve 540 as the gas coming from the first legs 530. In some embodiments, the second inlet line 570 includes at least one cut-off valve 572 upstream of the valve 540.

An outlet leg 580 extends from and is in fluid communication with each of the valves 540. The outlet leg 580 has an outlet end 584. The outlet end 584 can including any type of connection from a bare tube (i.e., no specific connection) to a fitting 582 that allows for connection of the outlet leg 580 to another component (e.g., a gas distribution assembly).

In some embodiments the length of tubing from the first junction 520 to each of the outlet ends 584 is substantially the same. Referring to FIG. 10, the length L1 of the combination of the first leg 530a, valve 540a and outlet leg 580a may be substantially the same as the length L2 for the first leg 530b, valve 540b and outlet leg 580b. As used in this specification and the appended claims, the term “substantially the same” used in this regard means that the length from the first junction to any of the outlet ends is within 5%, 2%, 1%, 0.5% or 0.25% relative to the average of all lengths from the first junction to all of the outlet ends. Some variation in the length of the tubing from the first junction to the end of each outlet leg is expected. When the legs are substantially the same, the gas pressure exiting each of the outlet legs are substantially the same in that any difference has minimal or no impact on the resulting process.

The valve 540 has two inputs legs and at least one outlet leg and can control the flow of fluid from at least the first leg 520 to the outlet leg 580. In some embodiments, the valve 540 controls the flow of gases from both the first leg 530 and the second inlet line 570 to the outlet leg 580. The valve 540 can be controlled by any suitable method including, but not limited to, electronic and pneumatic.

In one or more embodiments, the valve 540 only acts as a valve for the gas flowing through the first leg 520. The gas flowing through the second inlet line 570 passes through the valve 540 without affect. Thus, the valve 540 can act as a metering valve to allow some flow from the first leg 520 to enter the stream of gas flowing from the second inlet line 570. In one or more embodiments using the system of FIG. 8, the outlet leg 580 is connected to the first reactive gas input of a gas distribution assembly. During processing, a purge gas (e.g., nitrogen) is flowed at a constant rate through the second inlet line 570 into the processing chamber. A first reactive gas may flow through the first inlet line 510 to the first junction 520. The first reactive gas flow is split at the first junction into two first legs 530. The valve 540 can be opened to allow a flow of the first reactive gas from the first legs 530 into the outlet legs 580 to join the flow of purge gas. The purge gas is acting as a carrier for the reactive gas. When processing is complete, the valve 540 can be turned off so that no first reactive gas flows through the valve 540 into the outlet leg 580. At the same time, the purge gas flowing through the valve 540 from the second inlet line 570 is unaffected so the gas continues to flow to the gas distribution assembly.

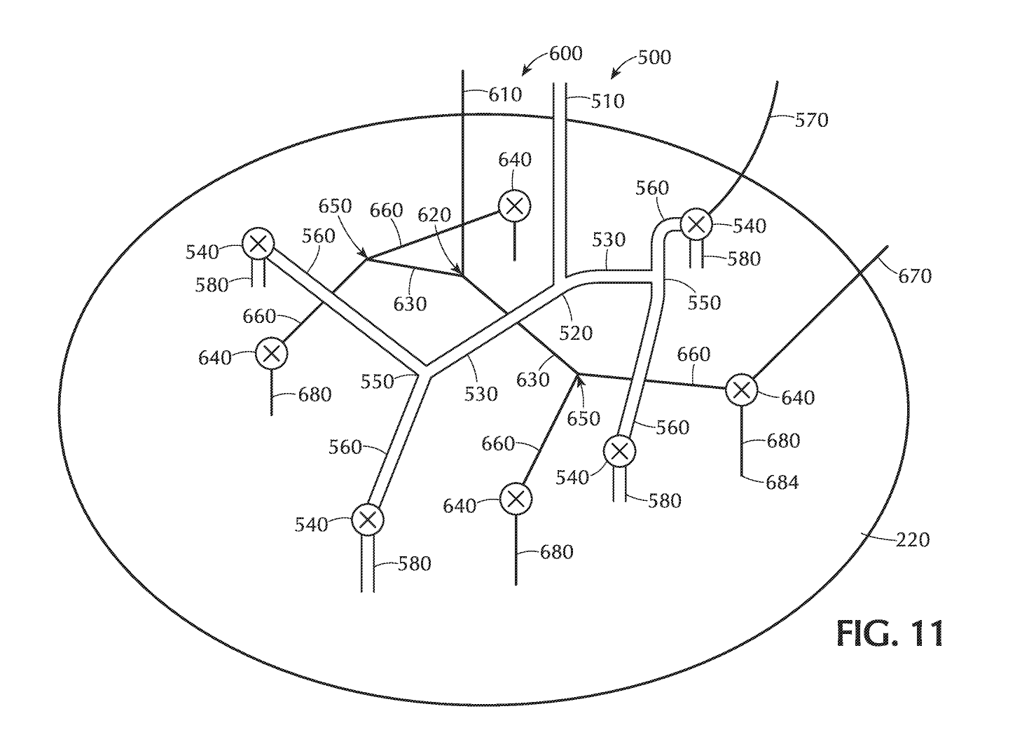

The system 500 can be used for any number of gas ports, meaning that there can by any number of outlet ends 584. In some embodiments, there are four outlet ends 584 which can be connected to, for example, a gas distribution assembly. Referring to FIG. 11, a gas distribution assembly 220 is shown with a first gas delivery system 500 and a second gas delivery system 600. Both the first gas delivery system 500 and second gas delivery system 600 have similar configurations as that of FIG. 9. The first gas delivery system 500 can be used to deliver a first reactive gas to each of the first reactive gas ports 125 (see FIG. 7). The second gas delivery system 600 can be used to deliver a second reactive gas to each of the second reactive gas ports 135 (see FIG. 7). Thus, the two systems in combination may be able to provide all of the reactive gases needed for the gas distribution assembly shown in FIG. 7. Additional systems can be added if additional reactive gases are included. For example, if the gas distribution assembly has four different types of reactive gases, there could be four gas delivery systems.

The first gas delivery system 500 shown in FIG. 11 includes all of the components of FIG. 9. The second gas delivery system 600 is similar and can have any of the same components described with respect to the first gas delivery system 500. Briefly, the second gas delivery system 600 includes a third inlet line 510 in fluid communication with a third junction 620. At least two third legs 630 are connected to and in fluid communication with the third junction 620. The embodiment of FIG. 11 has exactly two third legs 630 but more can be used, as in FIG. 10. Each of the third legs 630 are in fluid communication with at least one third valve 640. A fourth inlet line 670 is in fluid communication with each third valve 640. An outlet leg 680 is in fluid communication with each third valve 640 and ends in an outlet end 684. In some embodiments, each third valve 640 controls a flow of fluid from the third legs 630 to the outlet leg 680. In one or more embodiments, the distance from the third junction 620 to each of the outlet ends 684 are substantially the same.

In some embodiments, similar to FIG. 10, there are four third legs 630 connected to and in fluid communication with the third junction 620. Each of the four third legs 630 is in fluid communication with at least one third valve 640.

In the embodiments shown in FIG. 11, each of the third legs 630 is independently in fluid communication with a fourth junction 650 located downstream of the third junction 620 and upstream of the valves 640. At least two fourth legs 660 extend from and are in fluid communication with each of the fourth junctions 650 leading to the valves 640.

In some embodiments, one or more layers may be formed during a plasma enhanced atomic layer deposition (PEALD) process. In some processes, the use of plasma provides sufficient energy to promote a species into the excited state where surface reactions become favorable and likely. Introducing the plasma into the process can be continuous or pulsed. In some embodiments, sequential pulses of precursors (or reactive gases) and plasma are used to process a layer. In some embodiments, the reagents may be ionized either locally (i.e., within the processing area) or remotely (i.e., outside the processing area). In some embodiments, remote ionization can occur upstream of the deposition chamber such that ions or other energetic or light emitting species are not in direct contact with the depositing film. In some PEALD processes, the plasma is generated external from the processing chamber, such as by a remote plasma generator system. The plasma may be generated via any suitable plasma generation process or technique known to those skilled in the art. For example, plasma may be generated by one or more of a microwave (MW) frequency generator or a radio frequency (RF) generator. The frequency of the plasma may be tuned depending on the specific reactive species being used. Suitable frequencies include, but are not limited to, 2 MHz, 13.56 MHz, 40 MHz, 60 MHz and 100 MHz. Although plasmas may be used during the deposition processes disclosed herein, plasmas may not be included. Indeed, other embodiments relate to deposition processes under very mild conditions without a plasma.

According to one or more embodiments, the substrate is subjected to processing prior to and/or after forming the layer. This processing can be performed in the same chamber or in one or more separate processing chambers. In some embodiments, the substrate is moved from the first chamber to a separate, second chamber for further processing. The substrate can be moved directly from the first chamber to the separate processing chamber, or the substrate can be moved from the first chamber to one or more transfer chambers, and then moved to the predetermined separate processing chamber. Accordingly, the processing apparatus may comprise multiple chambers in communication with a transfer station. An apparatus of this sort may be referred to as a “cluster tool” or “clustered system”, and the like.

Generally, a cluster tool is a modular system comprising multiple chambers which perform various functions including substrate center-finding and orientation, degassing, annealing, deposition and/or etching. According to one or more embodiments, a cluster tool includes at least a first chamber and a central transfer chamber. The central transfer chamber may house a robot that can shuttle substrates between and among processing chambers and load lock chambers. The transfer chamber is typically maintained at a vacuum condition and provides an intermediate stage for shuttling substrates from one chamber to another and/or to a load lock chamber positioned at a front end of the cluster tool. Two well-known cluster tools which may be adapted for the present disclosure are the Centura® and the Endure®, both available from Applied Materials, Inc., of Santa Clara, Calif. However, the exact arrangement and combination of chambers may be altered for purposes of performing specific steps of a process as described herein. Other processing chambers which may be used include, but are not limited to, cyclical layer deposition (CLD), atomic layer deposition (ALD), chemical vapor deposition (CVD), physical vapor deposition (PVD), etch, pre-clean, chemical clean, thermal treatment such as RTP, plasma nitridation, degas, orientation, hydroxylation and other substrate processes. By carrying out processes in a chamber on a cluster tool, surface contamination of the substrate with atmospheric impurities can be avoided without oxidation prior to depositing a subsequent film.

According to one or more embodiments, the substrate is continuously under vacuum or “load lock” conditions, and is not exposed to ambient air when being moved from one chamber to the next. The transfer chambers are thus under vacuum and are “pumped down” under vacuum pressure. Inert gases may be present in the processing chambers or the transfer chambers. In some embodiments, an inert gas is used as a purge gas to remove some or all of the reactants after forming the layer on the surface of the substrate. According to one or more embodiments, a purge gas is injected at the exit of the deposition chamber to prevent reactants from moving from the deposition chamber to the transfer chamber and/or additional processing chamber. Thus, the flow of inert gas forms a curtain at the exit of the chamber.

During processing, the substrate can be heated or cooled. Such heating or cooling can be accomplished by any suitable means including, but not limited to, changing the temperature of the substrate support (e.g., susceptor) and flowing heated or cooled gases to the substrate surface. In some embodiments, the substrate support includes a heater/cooler which can be controlled to change the substrate temperature conductively. In one or more embodiments, the gases (either reactive gases or inert gases) being employed are heated or cooled to locally change the substrate temperature. In some embodiments, a heater/cooler is positioned within the chamber adjacent the substrate surface to convectively change the substrate temperature.

The substrate can also be stationary or rotated during processing. A rotating substrate can be rotated continuously or in discreet steps. For example, a substrate may be rotated throughout the entire process, or the substrate can be rotated by a small amount between exposures to different reactive or purge gases. Rotating the substrate during processing (either continuously or in steps) may help produce a more uniform deposition or etch by minimizing the effect of, for example, local variability in gas flow geometries.

While the foregoing is directed to embodiments of the present disclosure, other and further embodiments of the disclosure may be devised without departing from the basic scope thereof, and the scope thereof is determined by the claims that follow.

What is claimed is:

1. A gas delivery system comprising:
a first inlet line in fluid communication with a first junction;
at least two first legs connected to and in fluid communication with the first junction, each of the at least two first legs in fluid communication with at least one valve;
a second inlet line in fluid communication with each valve; and
an outlet leg in fluid communication with each valve and ending in an outlet end,
wherein each valve controls a flow of fluid from the first legs to the outlet leg and a distance from the first junction to each of the outlet ends are substantially the same.

2. The gas delivery system of claim 1, wherein the valves control a flow of fluid in the second inlet line to the outlet leg.

3. The gas delivery system of claim 1, wherein the valves do not control the fluid flow in the second inlet line to the outlet leg.

4. The gas delivery system of claim 1, wherein there are four first legs connected to and in fluid communication with the first junction, each of the four first legs in fluid communication with at least one valve.

5. The gas delivery system of claim 1, wherein each of the first legs is independently in fluid communication with a second junction located downstream of the first junction and at least two second legs extend from each of the second junctions leading to the valves.

6. The gas delivery system of claim 1, wherein each of the outlet ends comprises a fitting.

7. The gas delivery system of claim 1, wherein the second inlet line has at least one cut-off valve upstream of the valve.

8. The gas delivery system of claim 1, wherein the valves are pneumatic.

9. The gas delivery system of claim 1, further comprising:
a third inlet line in fluid communication with a third junction;
at least two third legs connected to and in fluid communication with the third junction, each of the at least two third legs in fluid communication with at least one third valve;
a fourth inlet line in fluid communication with each third valve; and
an outlet leg in fluid communication with each third valve and ending in an outlet end,
wherein each third valve controls a flow of fluid from the third legs to the outlet leg and a distance from the third junction to each of the outlet ends are substantially the same.

10. The gas delivery system of claim 9, wherein there are four third legs connected to and in fluid communication with the third junction, each of the four third legs in fluid communication with at least one third valve.

11. The gas delivery system of claim 9, wherein each of the third legs is independently in fluid communication with a fourth junction located downstream of the third junction and at least two fourth legs extend from each of the fourth junctions leading to the valves.

12. A gas delivery system comprising:
a first inlet line in fluid communication with a first junction;
two first legs connected to and in fluid communication with the first junction, each of the at least two first legs in fluid communication with a second junction;
two second legs in fluid communication with each of the second junctions and a valve;
a second inlet line in fluid communication with each of the valves; and
an outlet leg in fluid communication with each of the valves and having an outlet end,
wherein each valve controls a flow of fluid from the first legs to the outlet leg and a distance from the first junction through the second junction to each of the outlet ends are substantially the same.

13. The gas delivery system of claim 12, wherein the valves control a flow of fluid in the second inlet line to the outlet leg.

14. The gas delivery system of claim 12, wherein the valves do not control the fluid flow in the second inlet line to the outlet leg.

15. The gas delivery system of claim 12, wherein each of the outlet ends comprises a fitting.

16. The gas delivery system of claim 12, wherein the second inlet line has at least one cut-off valve upstream of the valve.

17. The gas delivery system of claim 12, wherein the valves are pneumatic valves.

18. A processing chamber comprising:
a gas distribution assembly within the processing chamber, the gas distribution assembly comprising a plurality of elongate gas ports including at least one first reactive gas port and at least one second reactive gas port, each of the first reactive gas ports separated from each of the second reactive gas ports; and
a first gas delivery system in fluid communication with one of the first reactive gas ports and the second reactive gas ports, the first gas delivery system comprising:
a first inlet line in fluid communication with a first junction;
at least two first legs connected to and in fluid communication with the first junction, each of the at least two first legs in fluid communication with at least one valve;
a second inlet line in fluid communication with each valve; and
an outlet leg in fluid communication with each valve and one of the plurality of first reactive gas ports or the second reactive gas ports,
wherein each valve controls a flow of fluid from the first legs to the outlet leg and a distance from the first junction to each of the outlet ends are substantially the same.

19. The processing chamber of claim 18, wherein the valves do not control the fluid flow in the second inlet line to the outlet leg.

20. The processing chamber of claim 18, further comprising a second gas delivery system in fluid communication with the other of the first reactive gas ports and the second reactive gas ports from the first gas delivery system, the second gas delivery system comprising:
a third inlet line in fluid communication with a third junction;
at least two third legs connected to and in fluid communication with the third junction, each of the at least two third legs in fluid communication with at least one third valve;
a fourth inlet line in fluid communication with each third valve; and
an outlet leg in fluid communication with each third valve and ending in an outlet end,
wherein each third valve controls a flow of fluid from the third legs to the outlet leg and a distance from the third junction to each of the outlet ends are substantially the same.
